(19) United States
(12) Patent Application Publication
(10) Pub. No.: US 2016/0266191 A1
(43) Pub. Date: Sep. 15, 2016

(54) INSPECTION APPARATUS AND INSPECTION METHOD

(71) Applicant: Kabushiki Kaisha Toshiba, Minato-ku (JP)

(72) Inventor: Motoki KADOWAKI, Yokkaichi (JP)

(73) Assignee: Kabushiki Kaisha Toshiba, Minato-ku (JP)

(21) Appl. No.: 14/840,330

(22) Filed: Aug. 31, 2015

Related U.S. Application Data
(60) Provisional application No. 62/130,945, filed on Mar. 10, 2015.

(51) Int. Cl. G01R 31/08; G01R 31/02; G01R 31/04

(52) U.S. Cl. CPC G01R 31/08; G01R 31/04; G01R 31/021

(57) ABSTRACT

In accordance with an embodiment, an inspection apparatus includes a detecting part and a control part. The detecting part detects a signal generated from a first layer including a wiring line or a contact due to application of an energy beam to the first layer. The control part sets an inspection area on the basis of a position of the wiring line or the contact that may be a defect in the first layer obtained by the signal and of information indicating an electric connection destination of the wiring line or the contact that may be the defect. The set inspection area includes a wiring line or a contact in a second layer different from the first layer. The second layer is electrically connected to the wiring line or the contact that may be the defect in the first layer.

### CROSS REFERENCE TO RELATED APPLICATIONS

This application is based upon and claims the benefit of U.S. provisional Application No. 62/130,945, filed on Mar. 10, 2015, the entire contents of which are incorporated herein by reference.

### FIELD

Embodiments described herein relate generally to an inspection apparatus and an inspection method.

### BACKGROUND

In a semiconductor manufacturing process, an apparatus of a scanning electron microscope (hereinafter briefly referred to as an “SEM”) type is used to inspect a pattern on a wafer for defects, observe the defects detected by this inspection, and measure pattern dimensions.

In the inspection of the SEM type, a part in which a voltage contrast is generated in a wiring line or a contact is often detected and then reviewed to detect defects, however, the very part in which an abnormality is occurring is not observed. Therefore, if, for example, it is found out that a certain contact has generated a voltage contrast that is darker than those in other contacts, it is not clear whether this contrast abnormality is attributed to faulty conduction of the contact or attributed to faulty conduction of the wiring line to which the contact is connected.

In order to find the root cause of the defect, it is necessary to cut out a sample by processing and analyze its section to discover abnormal parts, or analyze the diameter of a hole that is likely to have caused the faulty conduction or analyze a measurement value of the width of the wiring line.

Thus, there is a problem in the inspection of the SEM type is in that it takes time to investigate the root cause of the detected abnormality.

### BRIEF DESCRIPTION OF THE DRAWINGS

In the accompanying drawings:

FIG. 1 is an example of a block diagram showing the general configuration of an inspection apparatus according to one embodiment;

FIGS. 2 to 5 are examples of diagrams illustrating several examples of inspections that use the inspection apparatus shown in FIG. 1; and

FIG. 6 is an example of a flowchart showing the general procedure of an inspection method according to one embodiment.

### DETAILED DESCRIPTION

In accordance with an embodiment, an inspection apparatus includes a detecting part and a control part. The detecting part detects a signal generated from a first layer including a wiring line or a contact due to application of an energy beam to the first layer. The control part sets an inspection area on the basis of a position of the wiring line or the contact that may be a defect in the first layer obtained by the signal and of information indicating an electric connection destination of the wiring line or the contact that may be the defect. The set inspection area includes a wiring line or a contact in a second layer different from the first layer. The second layer is electrically connected to the wiring line or the contact that may be the defect in the first layer.

Embodiments will now be explained with reference to the accompanying drawings. Like components are provided with like reference signs throughout the drawings and repeated descriptions thereof are appropriately omitted. It is to be noted that the accompanying drawings are depicted in order to illustrate the invention and assist in the understanding of the illustration, and that the shapes, dimensions, and ratios and so on in each of the drawings may be different in some parts from those in an actual apparatus.

In the specification of the present application, “stacking” not only includes stacking layers in contact with each other but also includes stacking layers with another layer interposed therebetween. “Providing on” not only includes providing a layer in direct contact with a layer but also includes providing a layer on a layer with another layer interposed therebetween. A “top surface” of a via refers to one of two end faces of the via that locates opposite to a wafer side, and a “rear surface” of the via refers to one of the two end faces of the via that locates on the wafer side. Moreover, terms indicating directions such as “upper” and “lower” in the explanation mean relative directions when a later-described wafer side is a lower side. Therefore, the directions may be different from actual directions based on gravitational acceleration directions.

In the case described below by way of example, a single scanning electron microscope is used when a wafer flows from an upstream manufacturing line to a downstream manufacturing line so that wiring layers are sequentially stacked on the wafer. Therefore, when the wiring layer different from the wiring layer currently under inspection is inspected, a wafer is taken from another manufacturing line in which a target wiring layer is formed as a topmost layer, and a sample currently placed in a sample room is taken and replaced with the wafer to carry on the inspection.

However, this is not a restriction. As will be described later, a scanning electron microscope may be placed in each manufacturing line, and an inspection result obtained in the scanning electron microscope of an arbitrary manufacturing line may be transmitted online or offline and thereby fed back or fed forward to the scanning electron microscope of another manufacturing line, so that an inspection may be independently conducted for each manufacturing line.

(A) Inspection Apparatus

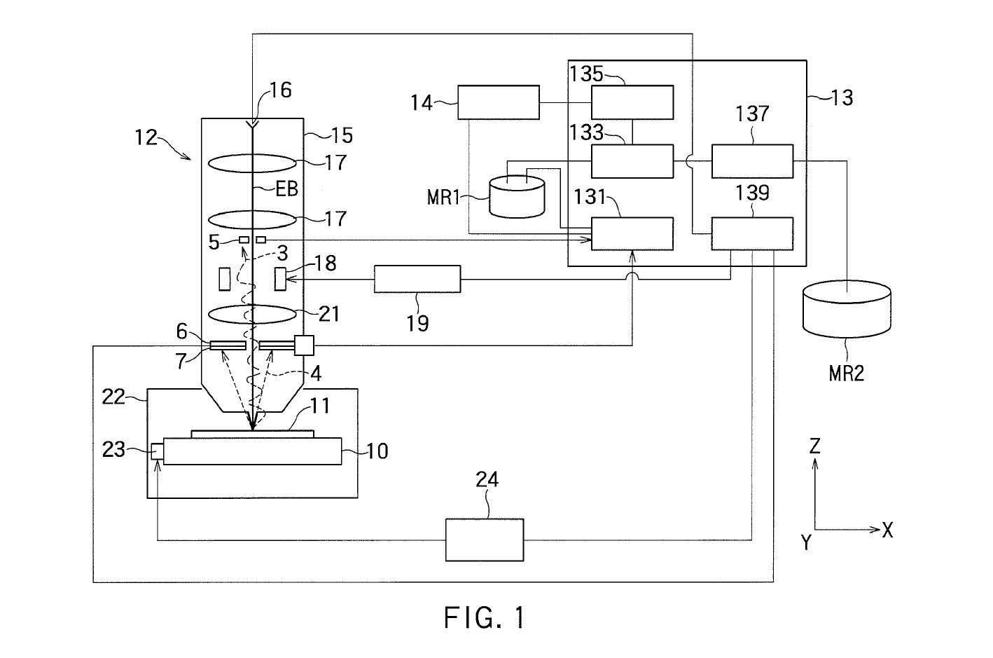

FIG. 1 is an example of a block diagram showing the general configuration of an inspection apparatus according to one embodiment. The pattern inspection apparatus shown in FIG. 1 includes a scanning electron microscope 12, a control computer 13, a scan control circuit 19, an actuator control circuit 24, a monitor 14, and memory devices MR1 and MR2.

The scanning electron microscope 12 includes a column 15 and a sample room 22.

The column 15 is provided with an electron gun 16, a condenser lens 17, a deflector 18, an objective lens 21, a secondary electron detector 5, and a reflection electron detector 6.

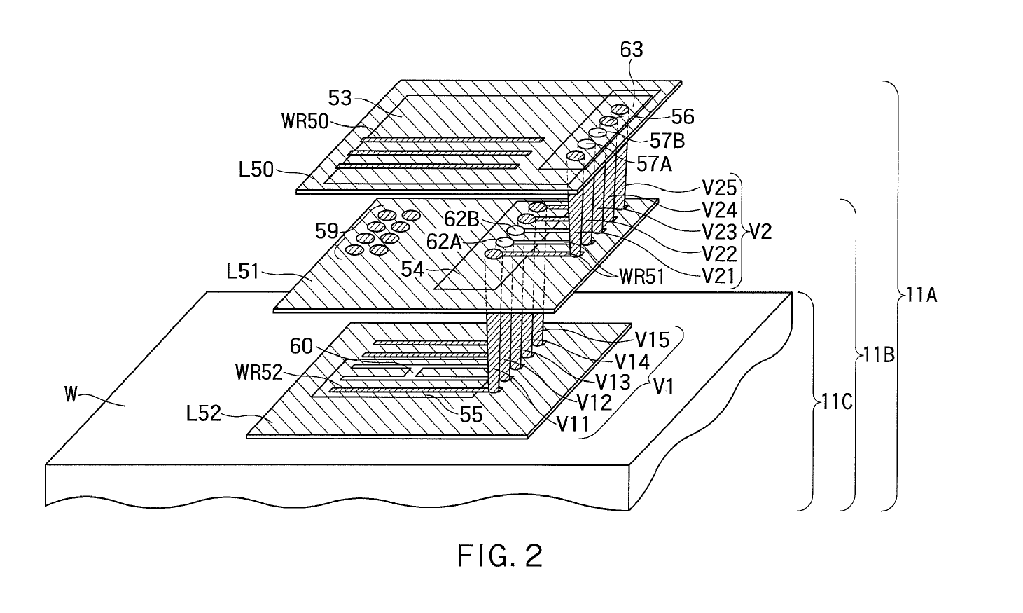

A stage 10 and an actuator 23 are provided in the sample room 22. The stage 10 supports a sample 11 (see FIG. 2 to FIG. 5) in which an inspection target circuit pattern is formed on a wafer.

The control computer 13 includes an image formation part 131, a defect estimating part 133, a defect detecting part 135, an inspection area setting part 137, and a control signal generating part 139.

The control signal generating part 139 is connected to the electron gun 16, an energy filter 7, the scan control circuit 19, and the actuator control circuit 24, and generates various command signals to control these instruments and circuits.

The scan control circuit 19 is connected to the deflector 18 in the column 15. The actuator control circuit 24 is connected to the actuator 23 in the sample room 22, and generates a signal for driving the stage 10 in accordance with the command signal sent from the control signal generating part 139 and sends the signal to the actuator 23.

The electron gun 16 generates an electron beam EB in accordance with the command signal sent from the control signal generating part 139 and then emits the electron beam EB toward the sample 11. The emitted electron beam EB is condensed by the condenser lens 17, and then applied to the sample 11 after the focal position of the electron beam EB is adjusted by the objective lens 21. In the present embodiment, the electron beam EB is, for example, an energy beam.

The scan control circuit 19 generates a deflection control signal in accordance with the command signal sent from the control signal generating part 139. The deflector 18 forms a deflection electric field or a deflection magnetic field in accordance with the deflection control signal supplied from the scan control circuit 19, and suitably deflects the electron beam EB in an X-direction or a Y-direction. Thereby, the surface of the sample 11 is scanned with the electron beam EB.

As a result of the application of the electron beam EB, a relatively low-energy secondary electron 3 and a relatively high-energy reflection electron 4 are generated from the surface of the sample 11.

The secondary electron 3 is mainly detected by the detector 5, and the reflection electron 4 is mainly detected by the detector 6. Both the detectors 5 and 6 are connected to the image formation part 131, and detection signals of the respective detectors are sent to the image formation part 131. In this instance, a proper voltage is applied to the energy filter 7 in accordance with a control signal from the control signal generating part 139 in such a manner that the reflection electron 4 is filtered in accordance with its energy and reaches the detector 6.

The image formation part 131 processes the detection signals sent from the detectors 5 and 6 to generate an image (SEM image) of the pattern on the sample surface, and stores the image in the memory device MR1 and also displays the image by the monitor 14.

The stage 10 is movable in the X-direction, the Y-direction, and a rotational direction, and the actuator 23 moves the stage 10 in accordance with a control signal generated by the actuator control circuit 24 under an instruction from the control signal generating part 139.

The defect estimating part 133 takes the SEM image from the memory device MR1, detects a place estimated to be defective in a via contact or a wiring line (hereinafter referred to as an “estimated defective place”) by, for example, die-to-die or cell-to-cell comparative/relative evaluation (a place which is estimated to be a defect but which has not been determined to be an abnormal place yet is hereinafter referred to as an “estimated defect”), and sends its positional information to the defect detecting part 135 and the inspection area setting part 137.

A database regarding the circuit placement (layout) of the sample 11 is stored in the memory device MR2. Such a database is preferably, but not exclusively, design data, and may be a data table in which a defect is associated with the position of an element on the circuit.

The inspection area setting part 137 accesses the database in the memory device MR2, searches for the contact or the wiring line electrically connected to the estimated defective place, thereby sets additional inspection areas (a second inspection area, a third inspection area . . . an n-th inspection area), and sends these additional inspection areas to the control signal generating part 139.

When the additional inspection area needs to be inspected as a result of the inspection of an arbitrary inspection area (first inspection area) of the first sample 11 mounted on the stage 10, the first sample 11 is replaced with a different sample in which the layer including the additional inspection area (e.g. the second inspection area) is formed.

If the control signal generating part 139 again actuates the scanning electron microscope 12, a signal from the second inspection area is then sent to the image formation part 131, and the defect estimating part 133 judges whether there is any estimated defective place.

When the defect estimating part 133 judges that there is an estimated defective place in the second inspection area, the defect estimating part 133 displays its positional information on the monitor 14, and also sends the positional information to the defect detecting part 135. The defect detecting part 135 specifies an abnormal place in the sample from the positional information regarding the estimated defective place from the first and second inspection areas, and displays the abnormal place on the monitor 14.

When judging that there is no estimated defective place in the second inspection area, the defect estimating part 133 sends the result of this judgment to the defect detecting part 135. When the second inspection area is located in a higher layer than the first inspection area (opposite to a wafer W), the defect detecting part 135 judges that the estimated defect in the first inspection area is attributed to a pseudo defect, and displays the judgment result on the monitor 14.

Several examples of defect inspections that use the inspection apparatus shown in FIG. 1 are described with reference to FIG. 2 to FIG. 5. It is to be noted that in FIG. 2 to FIG. 5, oblique lines are drawn to indicate gradation differences (the degrees of pixel values) in the sample image by the width of the pitch of the lines in such a manner as to facilitate visual recognition, and do not show the materials of components.

In addition, in FIGS. 2-5, areas surrounding line and space patterns are depicted as brighter than normal lines, but this is not a restriction. It is to be noted that gradation difference between a wire and its surrounding area may be reversed depending on a material of the wiring and a formation manner thereof (e.g. whether the wiring is formed in a line and space pattern or embedded within a layer) and so on.

### (1) Example 1

FIG. 2 is a composition diagram of sample images obtained by Example 1. In FIG. 2, composite voltage contrast images of samples 11A, 11B, and 11C are schematically shown.

Patterns are formed to be stacked on the wafer W in the manufacturing process of a semiconductor device, so that a layer L52, a layer L51, and a layer L50 are created in this order in the sample 11A in FIG. 2

The sample 11C is a sample in which the process up to the formation of the layer L52 including a wiring line WR52 on the wafer W has been finished. The sample 11B is a sample in which the process up to the formation of a via V1 and the layer L51 including a hole pattern 59 and a wiring line WR51 has been finished in addition to the process up to the sample 11C. Moreover, the sample 11A is a sample in which a via V2 and the layer L50 including a wiring line WR50 are further formed in addition to the process up to the sample 11B.

The wiring lines WR52, WR51, and WR50 of the layer L52, the layer L51, and the layer L50 are all formed by line-and-space patterns.

The interlayer via V1 is formed to electrically connect one end of the wiring line WR52 of the layer L52 and one end of the wiring line WR51 of the layer L51.

The interlayer via V2 is formed from the other end of the wiring line WR51 of the layer L51 to the layer L50, but is designed not to be electrically connected to the wiring line WR50.

In an inspection of an SEM type, inspecting all the layers requires considerable time, only some of the layers are thus inspected in many cases. Even if all the layers are inspected, scanning all the areas is not realistic, and some of the areas are only scanned in general.

However, the first scan needs to be performed in a wide range because it is not known at all whether there is any defect or where, if any, a defect is present.

Accordingly, the inspection area setting part 137 (see FIG. 1) sets a wide inspection area 53 as the first inspection area for the layer L50 of the sample 11A, and sends the first inspection area to the control signal generating part 139. The scanning electron microscope 12 is actuated by a control signal from the control signal generating part 139, so that the inspection area 53 is scanned with a beam, a detection signal is sent to the image formation part 131 where an SEM image is generated, and the SEM image is stored in the memory device MR1. The defect estimating part 133 detects an estimated defective place in the SEM image.

In the example shown in FIG. 2, estimated defective places 57A and 57B are detected on the top surfaces of vias V22 and V23. Here, the estimated defective places 57A and 57B are detected as voltage contrast defects that are different in brightness from the contacts of surrounding vias V21 and V24 in an image comparison of via contacts. From the difference of contrast, it is estimated that the vias V22 and V23 have electric leakages on the circuits compared to the other vias. However, it is not possible to discover an abnormal place solely from this first scan.

Thus, the inspection area setting part 137 accesses layout information stored in the memory device MR2 to search for a circuit (electric connection destination) to which the estimated defective places 57A and 57B are electrically connected, and ascertains the wiring line or the contact hole to which the estimated defective places 57A and 57B are connected in the upper layer and lower layer of the layer L50. When there are more than one estimated defective places, all of the defects or those that are sampled are searched.

In the example shown in FIG. 2, the range from the layer L50 where the estimated defective places 57A and 57B exist to the wiring line WR51 of the layer L51 immediately under the layer L50 and vias V12 and V13 is searched.

The inspection area setting part 137 then sets an additional inspection area from the search result of the circuit to which the estimated defective places are electrically connected. In the example shown in FIG. 2, an area 54 including the wiring line WR51 and the top surfaces of the vias V12 and V13 in the layer L51 is set as the second inspection area. The second inspection area may be determined so that the wiring line WR51 and the top surfaces of the vias V12 and V13 are only included or may be determined so that all the neighboring similar patterns (e.g. the top surfaces of vias V11, V14, and V15) are included.

If the second inspection area is set, the sample 11B in which the process up to the formation of the layer L52, the via V1, and the layer L51 has been finished is extracted from the upstream manufacturing line. The sample 11B is replaced with the sample 11A, and the sample 11A is put in the sample room 22, and mounted on the stage 10. The area 54 is scanned with the electron beam EB, and an SEM image of the area 54 is acquired in the layer L51 to conduct a defect inspection. Therefore, the pattern (the hole pattern 59 in the example in FIG. 2) that is not electrically related to the estimated defective places 57A and 57B does not need to be scanned, so that estimated defective places 62A and 62B can be detected in a short time and efficiently inspected.

Moreover, the layer L51 immediately under the first inspection area is not exclusively inspected, and the lower layer L52 can also be continuously inspected, which is preferable to find the root cause of the fault.

Specifically, the inspection area setting part 137 again accesses the layout information stored in the memory device MR2, and searches for the circuit in the lower layer to which the estimated defective places 62A and 62B detected in the second inspection area are electrically connected. That is, the inspection area setting part 137 ascertains the wiring line or the contact hole to which the estimated defective places 62A and 62B are connected in the layer L52 which is the lower layer of the layer L51. In the example shown in FIG. 2, the wiring line WR52 of the layer L52 is searched.

Thus, the inspection area setting part 137 further sets, as an additional inspection area (the third inspection area in this example), an area 55 including the wiring line electrically connected to the vias V12 and V13 and the wiring line electrically connected to the via V11 adjacent to the via V12 on the side opposite to via V13, for example, within the wiring line WR52 in the layer L52. Consequently, inspection efficiency can be higher than when the area covering the entire region of the wiring line WR52 is set as the third inspection area.

Then the sample 11C in which the process up to the formation of the layer L52 has been finished is extracted from the upstream manufacturing line. The sample 11B is replaced with the sample 11C, and the sample 11C is put in the sample room 22, and mounted on the stage 10. The area 55 is scanned with the electron beam EB, an SEM image of the area 55 is acquired in the layer L52, and the defect estimating part 133 conducts a defect inspection. Therefore, in the example in FIG. 2, a short-circuit defect 60 is detected as an estimated defective place in the part of the wiring line WR52 of the layer L52 electrically connected to the vias V12 and V13.

Information regarding the estimated defective places described above is displayed by the monitor 14, and also sent to the defect detecting part 135 from the defect estimating part 133. The defect detecting part 135 analyzes the sent estimated defective places to judge the root cause of the defect, and displays the judgment result on the monitor 14. In the example shown in FIG. 2, it is discovered that the abnormal place which becomes the root cause of the estimated defective places 57A, 57B, 62A, and 62B is the short-circuit defect 60 in the wiring line WR52 of the layer L52 in a short time.

In the manufacturing process of a semiconductor device, a large number of wafers sequentially flow in a line. If the inspection target is quickly changed from the layer L50 into the inspection areas in the layers L51 and L52 of the previous process from the inspection result of the layer L50, a fatal defect in the succeeding wafer can be discovered early.

When the area 54 in the layer L51 is set as the first inspection area and the detection of the abnormal place which becomes the root cause of the defect is desired, the defect estimating part 133 searches the lower layer for electric connection of the circuit as described above. In contrast, if the defect estimating part 133 searches the upper layer, different advantageous effects are obtained.

In the example shown in FIG. 2, the area 54 in the layer L51 of the sample 11B is set as the first inspection area, and the estimated defective places 62A and 62B are detected by the scanning of the area 54. In this case, if the inspection area setting part 137 searches the upper layer L50 for the electric connection of these estimated defective places by accessing the database in the memory device MR2, an area 63, for example, in the layer L50 is derived.

If the estimated defective places 62A and 62B detected in the layer L51 are pseudo defects, no estimated defective places are detected even by the scanning of the second inspection area 63.

On the contrary, if the estimated defective places 62A and 62B are true defects, estimated defective places corresponding to the estimated defective places 62A and 62B are detected from the second inspection area 63 as indicated by the signs 57A and 57B in FIG. 2.

Thus, when the estimated defective places in the first inspection area 54 are true defects, the upper layer is searched for electric connection, and reproducibility of defect detection is obtained, so that detection accuracy in the layer L51 can be checked.

When stronger voltage contrast is obtained in the SEM image from the layer L50 than in the SEM image obtained from the layer L51, an inspection with higher sensitivity becomes possible, and the capture rate of defects improves.

Here, the inspection area 63 smaller in size than the above-mentioned inspection area 53 can be set for the following reasons. When the inspection starts from the layer L50 in the sample 11A, a wide range needs to be inspected because it is not known in the first place where the voltage contrast defect exists. In contrast, when the inspection starts from the layer L51 of the sample 11B, the wiring line or the via electrically connected to the detected estimated defective places 62A and 62B is searched, so that the inspection area can be narrowed down.

Although the same scanning electron microscope 12 is used for all the inspection areas (all the samples) in the case described above, this is not a restriction. The scanning electron microscope 12 may be placed in each manufacturing line, information regarding the inspection areas set by the inspection area setting part 137 may be transmitted online or offline, and an inspection may be independently conducted for each manufacturing line. In this case, a dead time resulting from the replacement of the sample 11 can be omitted, so that a more efficient inspection is possible.

Although one or more scanning electron microscopes 12 are used for all the inspection areas in the case described above, it is not always necessary to use the scanning electron microscope 12 in and after the second inspection area, and similar advantageous effects can also be obtained by the use of a microscope that uses light or laser light, for example, an apparatus capable of detecting secondary electrons and reflection electrons emitted from the sample by the application of light.

The inspection procedure described above is not exclusively intended for defect inspection, and may be used together at the time of a defect review or length measurement. For example, a scan area is limited in the case of the defect review, so that the probability of the discovery of a defect is higher even if a small area is reviewed. Since the length measurement is also conducted in the inspection area in which the probability of the existence of an electric defect is high in the length measurement, there is a high probability that an abnormal value at which the width of the wiring line or the diameter of a hole has deviated from an estimation may be obtained, and an abnormality in the manufacturing process can be effectively discovered.

### (2) Example 2

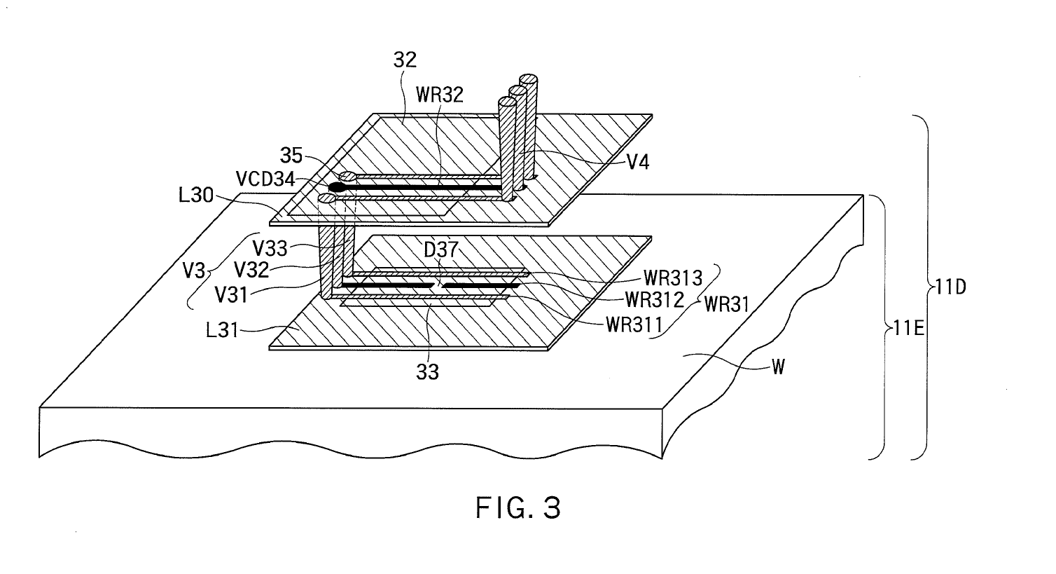

FIG. 3 is an example of a composition diagram of sample images obtained by Example 2. In FIG. 3, a voltage contrast image in which samples 11D and 11E are composed is schematically shown.

The sample 11E is a sample in which the process of forming a layer L31 including a wiring line WR31 on the wafer W has been finished. The sample 11D is a sample in which the process of forming a via V3 (V31 to V33), a layer L30 including a wiring line WR32, and a via V4 has been finished in addition to the process up to the sample 11E.

The wiring line WR31 of the layer L31 and the wiring line WR32 of the layer L30 are all formed by line-and-space patterns. Alternatively, the wirings WR31, 32 may be formed into wiring patterns which are embedded in the insulating layer. The via V3 is formed so as to electrically connect one end of the wiring line WR31 of the layer L31 and one end of the wiring line WR32 of the layer L30. The via V4 is formed so as to extend upward (in a direction perpendicular to the surface of the wafer W) from the other end of the wiring line WR32.

In the present example, an area 32 in the layer L30 of the sample 11D is set as the first inspection area, and a dark voltage contrast defect VCD34 is detected in a top surface 34 of a via V32 in the SEM image obtained by the scanning with the electron beam EB.

Normally, when a defect is detected in a via contact, it is preferable to search the lower layer of the layer L30 rather than the upper layer for electric connection in order to discover the abnormal place which becomes the root cause.

In the example shown in FIG. 3, the wiring line WR32 is electrically connected to the via V32, and the via V4 electrically connected to an unshown upper layer via the wiring line WR32 also exists. However, the generation of voltage contrast is weak in the SEM image acquired from the top surface of the via V4. This is because the length of the wiring line is usually greater than the length of the via (the depth of the via hole), so that if a normal wiring line intervenes between the upper and lower vias, the electric capacity of the normal wiring line becomes predominant, and no generation of voltage contrast is seen in the via contact in the upper layer.

Accordingly, the inspection area setting part 137 (see FIG. 1) searches the lower layer of the layer L30 for electric connection, and sets, as the second inspection area, an area 33 including wiring lines WR311 to WR313 electrically connected to the vias V31 to V33 in the region of the layer L31.

Then the sample 11E is extracted from the upstream manufacturing line. The sample 11E is replaced with the sample 11D, and the sample 11E is put in the sample room 22 of the scanning electron microscope 12, and mounted on the stage 10. The area 33 is scanned with the electron beam EB, an SEM image of the area 33 is acquired, and a defect inspection is conducted. Therefore, as shown in FIG. 3, in the present example, the defect estimating part 133 detects an open defect D37 in a wiring line WR312, and the defect detecting part 135 judges that the open defect D37 is the abnormal place which becomes the root cause of the voltage contrast abnormality in the top surface VCD34 of the via V32 that has been estimated to be the defect.

### (3) Example 3

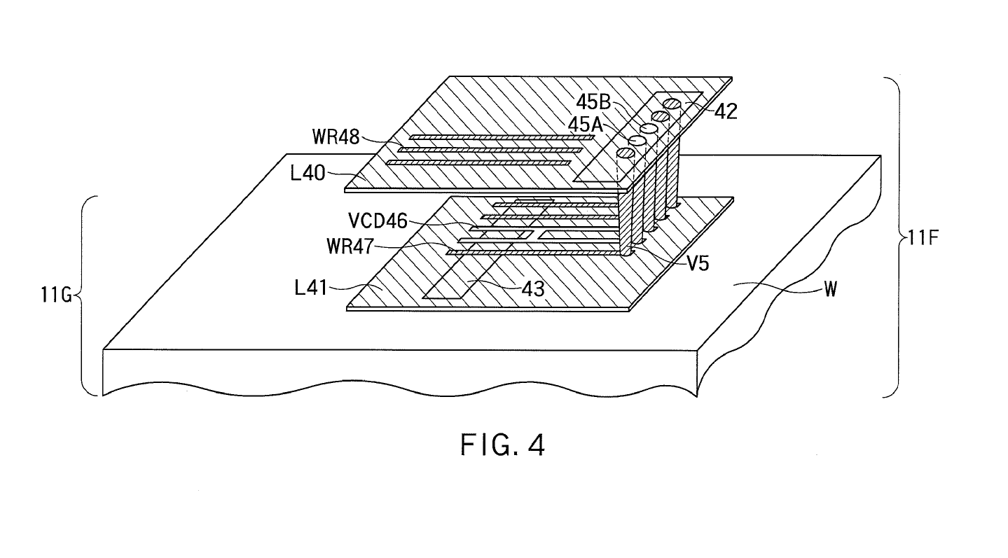

FIG. 4 is an example of a composition diagram of sample images obtained by Example 3. In FIG. 4, a voltage contrast image in which the samples 11F and 11G are composed is schematically shown.

The sample 11G is a sample in which the process of forming, on the wafer W, a layer L41. including a wiring line WR47, and a via V5 extending to a layer L40 from one end of the wiring line WR47 has been finished. The sample 11F is a sample in which the process of forming a layer L40 including a wiring line WR48 has been finished in addition to the process up to the sample 11G.

Both the wiring line WR47 of the layer L41 and the wiring line WR48 of the layer L40 are formed by line-and-space patterns. However, the wiring line WR48 of the layer L40 is designed not to be electrically connected to the via V5.

In the present example, first, an area 43 of the sample 11G is set as the first inspection area, and an SEM image obtained by the scanning with the electron beam EB is inspected. Consequently, as shown in FIG. 4, the defect estimating part 133 (see FIG. 1) detects, as an estimated defective place, a bright voltage contrast defect VCD46 in the wiring line WR47.

When the estimated defective place is thus detected in the wiring line, it is generally preferable to search the upper layer of the wiring line rather than the lower layer for electric connection. This is because the electric capacity of the wiring line is higher than that of the via as described above, so that stronger voltage contrast is generated in the via contact in the upper layer manufactured at and after the formation of this wiring line.

In the present example as well, the inspection area setting part 137 searches the upper layer for the electric connection of the detected estimated defective place, and the inspection area setting part 137 sets, as the second inspection area, an area 42 including top surface of the via V5, and acquires and analyzes an SEM image of the area 42, and thereby detects voltage contrast defects 45A and 45B in the layer L40 as well.

As a result, it is possible to judge that the probability that the voltage contrast defect VCD46 detected by the scanning of the first inspection area with the electron beam may be a pseudo defect is low. Therefore, the defect detecting part 135 judges that an abnormal place which becomes the root cause exists on the wiring line WR47 of the layer L41.

Thus, according to the present example, the upper layer of the wiring line where the estimated defective place has been detected is searched for electric connection, and the second inspection area is then set, so that the accuracy of defect detection can be increased.

### (4) Example 4

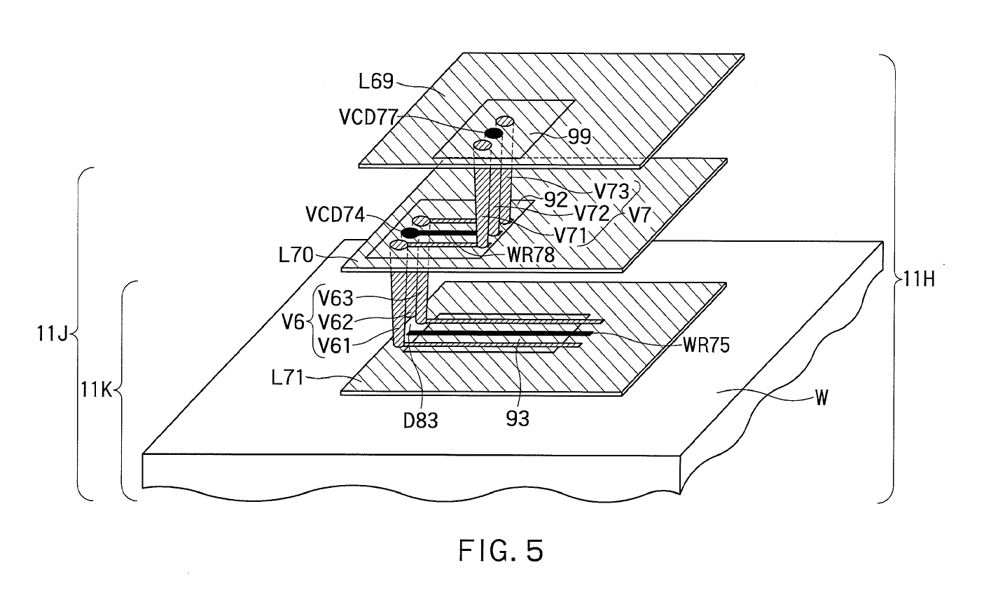

FIG. 5 is an example of a composition diagram of sample images obtained by Example 4. In FIG. 5, a voltage contrast image in which samples 11H, 11J, and 11K are composed is schematically shown.

The sample 11K includes the wafer W, and a layer L71 and a via V6 (V61 to V63) formed on the wafer W. The sample 11J further includes a layer L70 and a via V7 (V71 to V73) in addition to the configuration of the sample 11K. The sample 11H further includes a layer L69 in addition to the configuration of the sample 11J.

A wiring line WR75 of a line-and-space pattern is formed in the layer L71, and the via V6 is designed to extend toward the layer L70 in a direction perpendicular to the surface of the wafer W from one end of the wiring line WR75. A wiring line WR78 of a line-and-space pattern is formed in the layer L70, and one end of the wiring line WR78 is io designed to be connected to the top surface of the via V6. The other end of the wiring line WR78 is designed to be connected to the via V7, the via V7 is designed to extend toward the layer L69 in a direction perpendicular to the surface of the wafer W, and its top surface reaches the layer L69.

The wiring lines WR75 and WR78 may be formed so as to be embedded in an insulating layer in place of being formed as a line and space pattern.

In aforementioned Example 2, when a voltage contrast defect is detected in the via contact, satisfactory advantageous effects cannot be obtained even if the upper layer of this via contact is searched for an electric circuit because the capacity of the wiring line is relatively high. However, when the length of the wiring line is less than or equal to the length (depth) of the via, satisfactory advantageous effects may be obtained if the upper layer is searched for an electric circuit.

For example, in FIG. 5, the length of the wiring line WR78 in the layer L70 is less than or equal to the lengths of a via V62 and a via V72 to which the wiring line WR78 is electrically connected. Thus, the capacity of the wiring line WR78 is lower than, for example, that of the wiring line WR32 shown in FIG. 3. Therefore, voltage contrast defects can be generated in both the via V6 in the lower layer and the via V7 in the upper layer.

Firstly, explanation is made by providing an example in which a defect is generated in the via in the lower layer. For example, an area 99 in the layer L69 is set and inspected as the first inspection area. If the defect estimating part 133 detects a voltage contrast defect VCD77 in the top surface of the via V72 as shown in FIG. 5, the inspection area setting part 137 searches the pattern electrically connected to the via V72 toward the lower layer, and sets and inspects an area 92 as the second inspection area.

As a result, a voltage contrast defect VCD74 is detected in the top surface of the via V62 electrically connected to the wiring line WR78. However, in the example in FIG. 5, no abnormal place can be detected even if, for example, attention is focused on the wiring line WR78.

Here, when a relatively long wiring line intervenes as in the example in FIG. 3, the circuit in the higher layer is searched for, and an additional inspection area is set and inspected. Nevertheless, no abnormal place is discovered. In contrast, in the example shown in FIG. 5, the generation of the voltage contrast defect in the top surface of the via V62 is detected, and it is therefore technically meaningful to search for an electric circuit up to the layer L71 lower than the layer L70.

Thus, if an inspection is conducted after the electric circuit search in the layer L71 and the setting of the third inspection area, the open fault defect D37 in the lower wiring line may be detected, for example, as in the example in FIG. 3. Alternatively, as in the example in FIG. 5, when an area 93 is set and inspected as the third inspection area, an open defect D83 in the contact between the wiring line WR75 in the layer L71 and the via V62 may be judged to be an abnormal place as the root cause, though no abnormality/defect is discovered in the wiring line WR78 in the layer L70 after all.

Secondly, explanation is made by providing an example in which a defect is generated in the via in the upper layer. For example, if the area 92 is first set as the first inspection area and the area 99 in the layer L69 is then set and inspected as the second inspection area, the voltage contrast defect VCD77 is detected in the top surface of the via V72.

In addition, when the area 92 in the layer L70 is set as the first inspection area, the open defect D83 in the contact between the wiring line WR75 in the layer L71 and the via V62 may be judged to be an abnormal place as the root cause as in the case described above even if the area 93 in the layer L71 is set and inspected as the second inspection area.

The inspection apparatus according to at least one embodiment described above includes the defect estimating part 133 which processes a signal obtained in an inspection area in an arbitrary layer of a sample to acquire positional information regarding an estimated defective place, and the inspection area setting part 137 which checks the obtained positional information against information regarding the layout of a circuit pattern of the sample to set an additional inspection area in a layer different from the layer to which the estimated defective place belongs. Therefore, it is possible to specify an abnormal place which becomes the root cause and discover a fatal defect in the succeeding wafer early by feeding back the detected positional information regarding the estimated defective place and the information regarding the additional inspection area to the upstream manufacturing line.

In addition, the inspection apparatus according to at least one embodiment described above includes the defect estimating part 133 and the inspection area setting part 137. Therefore, if the detected positional information regarding the estimated defective place and the information regarding the additional inspection area are fed forward to a downstream manufacturing line, the downstream inspection area is narrowed down, and inspection efficiency thus improves. Moreover, when the detected estimated defect is a pseudo defect, this fact can be confirmed, so that a defect inspection can be accurately conducted.

(B) Inspection Method

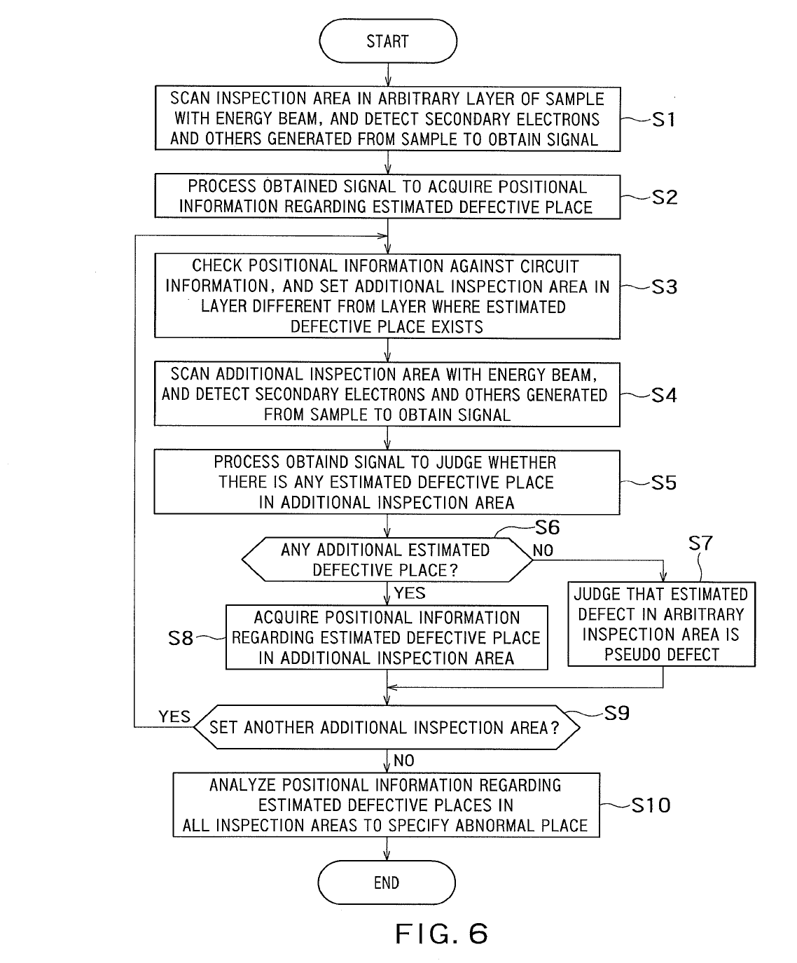

An inspection method according to one embodiment is described with reference to FIG. 6. FIG. 6 is an example of a flowchart showing the general procedure of the inspection method according to the present embodiment.

First, an arbitrary area in an arbitrary layer is set as a first inspection area in a sample provided with a circuit pattern including a plurality of wiring layers and an interlayer via, and this first inspection area is scanned with an energy beam to detect secondary electrons and reflection electrons generated from the sample and then acquire a signal (step S1).

The obtained signal is then processed to acquire positional information regarding an estimated defective place (step S2). For example, an SEM image is generated from the obtained signal, the potential contrast of this SEM image is compared with that of an SEM image obtained from an adjacent pattern of the same shape to detect a place estimated to be defective (an estimated defective place), and the position of this place is specified from a position on wafer coordinates.

The positional information regarding the estimated defective place is then checked against information regarding the layout of a circuit pattern to search for a contact hole or a wiring line electrically connected to the estimated defective place in a layer different from the layer to which the estimated defective place belongs, and an additional inspection area is set (step S3).

The set additional inspection area is then scanned with an energy beam, and secondary electrons and reflection electrons generated from the sample are detected to acquire a signal as in the case of the first inspection area (step S4).

The signal obtained from the additional inspection area is then processed, and whether there is any estimated defective place in the additional inspection area is judged (step S5).

When no estimated defective place can be detected in the additional inspection area (step S6, No), the estimated defect in the arbitrary inspection area is judged to be a pseudo defect (step S7). This can typically occur, for example, when an additional inspection area is selected from the upper layer as has been shown in Example 3 described above.

When an estimated defective place is detected in the additional inspection area (step S6, Yes), positional information regarding the estimated defective place detected in the additional inspection area is acquired (step S8).

When another additional inspection area needs to be set (step S9, Yes), the above-described procedure from step S3 to step S8 is then repeated until the detection of estimated defective places finishes in all the necessary inspection areas.

On the contrary, when the detection of estimated defective places has already finished in all the necessary inspection areas and no more additional inspection area needs to be set (step S9, No), the positional information regarding the estimated defective place in all the inspection areas obtained in the above-described procedure is analyzed, and an abnormal place which becomes the root cause is specified (step S10).

The inspection method according to at least one embodiment described above checks positional information regarding an estimated defective place detected in an inspection area in an arbitrary layer of a sample against information regarding the layout of a circuit pattern of the sample to set an additional inspection area in a layer different from the layer to which the estimated defective place belongs. Therefore, it is possible to specify an abnormal place which becomes the root cause and discover a fatal defect in the succeeding wafer early by feeding back the detected positional information regarding the estimated defective place and the information regarding the additional inspection area to the upstream manufacturing line.

In addition, in the inspection method according to at least one embodiment described above, the detected positional information regarding the estimated defective place and the information regarding the additional inspection area are fed forward to the downstream manufacturing line, so that the downstream inspection area is narrowed down, and inspection efficiency thus improves. Moreover, when the detected estimated defect is a pseudo defect, this fact can be confirmed, so that a defect inspection can be accurately conducted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An inspection apparatus comprising:
a detecting part configured to defect a signal generated from a first layer comprising a wiring line or a contact due to application of an energy beam to the first layer; and
a control part configured to set an inspection area on the basis of a position of the wiring line or the contact that may be a defect in the first layer obtained by the signal and of information indicating an electric connection destination of the wiring line or the contact that may be the defect, the set inspection area comprising a wiring line or a contact in a second layer different from the first layer, the second layer being electrically connected to the wiring line or the contact that may be the defect in the first layer.

2. The apparatus of claim 1, further comprising a defect detecting part configured to specify an abnormal place from the detected signal.

3. The apparatus of claim 1,
wherein the first layer is provided above a substrate, and
when the control part judges that a place that may be the defect is in the contact, the control part species, as the second layer, a layer located closer to the substrate than the first layer.

4. The apparatus of claim 1,
wherein the first layer is provided above a substrate, and
when the control part judges that a place that may be the defect is in the wiring line, the control part identifies, as the second layer, a layer located closer to the side opposite to the substrate than the first layer.

5. The apparatus of claim 1,
wherein when the control part judges that a place that may be the defect is in the wiring line in the first layer and when the length of the wiring line in the first layer is smaller than the length of a contact hole connected to the wiring line in the first layer, the control part identifies, as the second layers, two layers lying across the first layer.

6. The apparatus of claim 1,
wherein an area of the first layer to which the energy beam is applied is larger than the inspection area set in the second layer.

7. An inspection method comprising:
applying an energy beam to a first layer comprising a wiring line or a contact;
detecting a signal generated from the first layer;
processing the signal to acquire positional information regarding the wiring line or the contact that may be a defect; and
checking the obtained positional information against information indicating an electric connection destination of the wiring line or the contact that may be the defect to set an inspection area comprising a wiring line or a contact in a second layer different from the first layer, the second layer being electrically connected to the wiring line or the contact that may be the defect in the first layer.

8. The method of claim 7, further comprising specifying an abnormal place from the detected signal.

9. The method of claim 7,
wherein the first layer is provided above a substrate, and
when a place that may be the defect is judged as lying in the contact, a layer located closer to the substrate than the first layer is specified as the second layer.

10. The method of claim 7,
wherein the first layer is provided above a substrate, and
when a place that may be the defect is judged as lying in the wiring line, a layer located closer to the side opposite to the substrate than the first layer is specified as the second layer.

11. The method of claim 7,
wherein when that a place that may be the defect is judged as lying in the wiring line in the first layer and when the length of the wiring line in the first layer is smaller than the length of a contact hole connected to the wiring line in the first layer, two layers lying across the first layer is specified as the second layers.

12. The method of claim 7,
wherein an area of the first layer into which the energy beam is applied is larger than the inspection area set in the second layer.
